(19) United States
(12) Patent Application Publication
(10) Pub. No.: US 2009/0066244 A1
(43) Pub. Date: Mar. 12, 2009

(54) Encapsulated Organic Electronic Device With Improved Resistance To Degradation

(75) Inventors: Paolo TASSINI, Portici (IT); Maria Grazia MAGLIONE, Torre Del Greco (IT); Emma ROMANELLI, Napoli (IT); Paolo VACCA, Avellino (IT); Carla MINARINI, Salerno (IT)

Correspondence Address: GRAYBEAL JACKSON LLP, 155 - 108TH AVENUE NE, SUITE 350, BELLEVUE, WA, 98004-5973, US

(73) Assignee: STMicroelectronics S.r.I., Agrate Brianza (IT)

(21) Appl. No.: 12/209,176

(22) Filed: Sep. 11, 2008

(30) Foreign Application Priority Data
Sep. 11, 2007 (IT) TO2007U 000116

(51) Int. Cl. H01J 1/63; H01L 51/00; H01L 51/40

(52) U.S. Cl. 313/512; 257/40; 438/99; 257/E51.003

(57) ABSTRACT

An encapsulated organic electronic device is provided with: a substrate; at least one first elementary component and one second elementary component set above the substrate, each of said first and second elementary components being provided with a respective first electrode set above the substrate, a respective region of organic material set above the first electrode, and a respective second electrode set above the region of organic material at least partially in an area corresponding to the first electrode; and an encapsulation structure, defining an encapsulation space isolated from an external environment and designed to protect the first and second elementary components from the external environment. In particular, the regions of organic material of the first and second elementary components are separated and distinct from one another and are set entirely within the encapsulation space.

### PRIORITY CLAIM

The present application claims the benefit of Italian Patent Application Serial No. TO2007U 000116, filed Sep. 11, 2007, which application is incorporated herein by reference in its entirety.

### TECHNICAL FIELD

Embodiments of the present invention relate to an encapsulated organic electronic device and to a corresponding manufacturing process such as the manufacturing of organic LED devices (Organic Light-Emitting Diodes (OLEDs).

### BACKGROUND

As is known, the use of organic semiconductor materials has proven very promising for the production of electronic and optoelectronic devices such as, for example, photovoltaic devices, OLEDs, thin-film transistors (TFTs), solid-state lasers, and sensors. For example, OLED devices are currently used as functional units for the production of displays formed by an array of luminous pixels that can be addressed separately.

### SUMMARY

In a known manner, and as shown in FIG. 1, an OLED component 1 generally comprises: a substrate 2; a first electrode (anode) 3 and a second electrode (cathode) 4 provided above the substrate 2; and a layer of organic material 5, e.g., made of an electroluminescent conductive polymer, set between the first and second electrodes 3, 4. The layer of organic material 5 is formed, for example, by evaporation, over the entire substrate 2, and the electroluminescent area is defined by the portion of the layer of organic material 5 at which the first and second electrodes 3, 4 overlap. By appropriate electrical biasing of the electrodes, it is possible to generate a current inducing emission of a light radiation from the layer of organic material 5, due to the radioactive decay of an exciton generated by recombination of electrons injected by the cathode and holes injected by the anode. Depending on the material of which the substrate and the electrodes are made, OLED devices are distinguished into “bottom-emitting” and “top-emitting”. In the first case, the light radiation is emitted downwards through the substrate 2, made of a transparent material (for example, plastic or glass), the first electrode 3 is constituted by a transparent conductive material (for example, Indium Tin Oxide, or ITO), while the second electrode 4 is made of an opaque metal with low work function (for example, aluminium) to ensure sufficient injection of electrons in the layer of organic material. In the second case, the light radiation is emitted upwards through the second electrode 4, in this case constituted by a transparent conductive material, and both the first electrode 3 and the substrate 2 are made of opaque material (for example, respectively, aluminium and silicon or ceramic). In particular, FIG. 1 shows a cross section of an OLED component 1 of the bottom-emitting type, in which the direction of emission of the light radiation is indicated by the arrow.

OLED devices have a series of advantageous features, among which, for example, the low driving voltage, which enables low levels of consumption, good light efficiency, and low manufacturing costs (since it requires standard manufacturing techniques). However, the organic materials used in these devices undergo a rapid degradation in the presence of external agents such as light, oxygen and humidity (water vapor). In addition, the metals used for making the electrodes, due to their low work function, have a marked tendency to oxidize, causing degradation of the devices.

In order to limit the problem of rapid degradation of organic electronic devices in the presence of external agents, and to increase the long-term stability of the materials, the use of encapsulation structures has been proposed.

These encapsulation structures comprise, for example, a rigid cover (glass or metal) fixed to the substrate of the device by means of epoxy resin, formed in an inert atmosphere (nitrogen or argon); or else a thin film deposited directly on the active layers of the device. In the latter case, the thin film deposition process is somewhat critical insofar as it must not damage the underlying active layers, and the deposited film is required to have a series of rather stringent characteristics, among which: a low permeability to external agents; a good adhesion to underlying layers; a sufficient strength so as to enable the device to be handled without this causing damage; a thermal expansion coefficient similar to that of the underlying layers; and, in the case of flexible substrates, a sufficient degree of flexibility. It has been experimentally verified that the value of permeability to water vapor (Water Vapor Transmission Rate, or WVTR) that the encapsulation structures require for an OLED device to have a operating life higher than 10,000 hours is just 10⁻⁶ g/m²/day. Likewise, the required value of permeability to oxygen (Oxygen Transmission Rate, or OTR) has been experimentally determined to be comprised between 10⁻⁵ and 10⁻³ cm³/m²/day.

So far, organic electronic devices and corresponding manufacturing processes that prove altogether satisfactory, in particular as regards resistance to external agents and stability of the organic materials, have not been proposed.

The aim of embodiments of the present invention is consequently to provide processes, and devices formed by such processes, that will enable the aforementioned disadvantages and problems to be overcome, and in particular that will provide an organic electronic device with improved strength and stability.

### BRIEF DESCRIPTION OF THE DRAWINGS

For a better understanding of the present invention, embodiments thereof are now described purely by way of non-limiting example and with reference to the attached drawings, wherein:

FIG. 1 shows a cross section of an OLED component, of a known type;

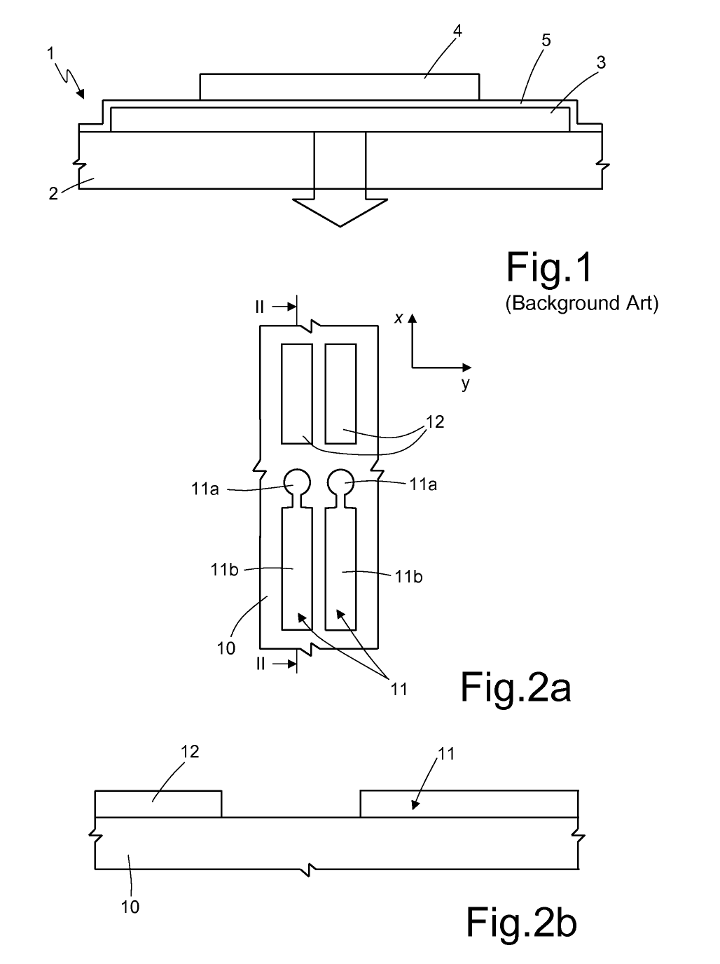

FIGS. 2a-5a show top plan views of an organic electronic device in successive steps of a corresponding manufacturing process according to a first embodiment of the present invention;

FIGS. 2b-5b show cross sections of the device of FIGS. 2a-5a taken along lines II-II-V-V;

FIGS. 6 and 7 show cross sections of variants of the organic electronic device of FIGS. 2a-5a;

FIGS. 8-12 show cross sections of an organic electronic device in successive steps of a corresponding manufacturing process according to a second embodiment of the present invention;

FIGS. 13-16 show top plan views of an organic electronic device in successive steps of a corresponding manufacturing process according to a third embodiment of the present invention; and

FIG. 17 shows an infrared image of a portion of an organic electronic device, with a superheating region indicated by the arrow.

### DETAILED DESCRIPTION

The following discussion is presented to enable a person skilled in the art to make and use the invention. Various modifications to the embodiments will be readily apparent to those skilled in the art, and the generic principles herein may be applied to other embodiments and applications without departing from the spirit and scope of the present invention. Thus, the present invention is not intended to be limited to the embodiments shown, but is to be accorded the widest scope consistent with the principles and features disclosed herein.

A manufacturing process according to a first embodiment of the present invention is now described, envisaging the formation of an organic electronic device comprising a plurality of elementary components (in particular, bottom-emitting OLEDs) made at least in part of organic materials. In what follows, for reasons of simplicity of illustration, just two elementary components will be illustrated, but it should be clear that any number thereof may be formed.

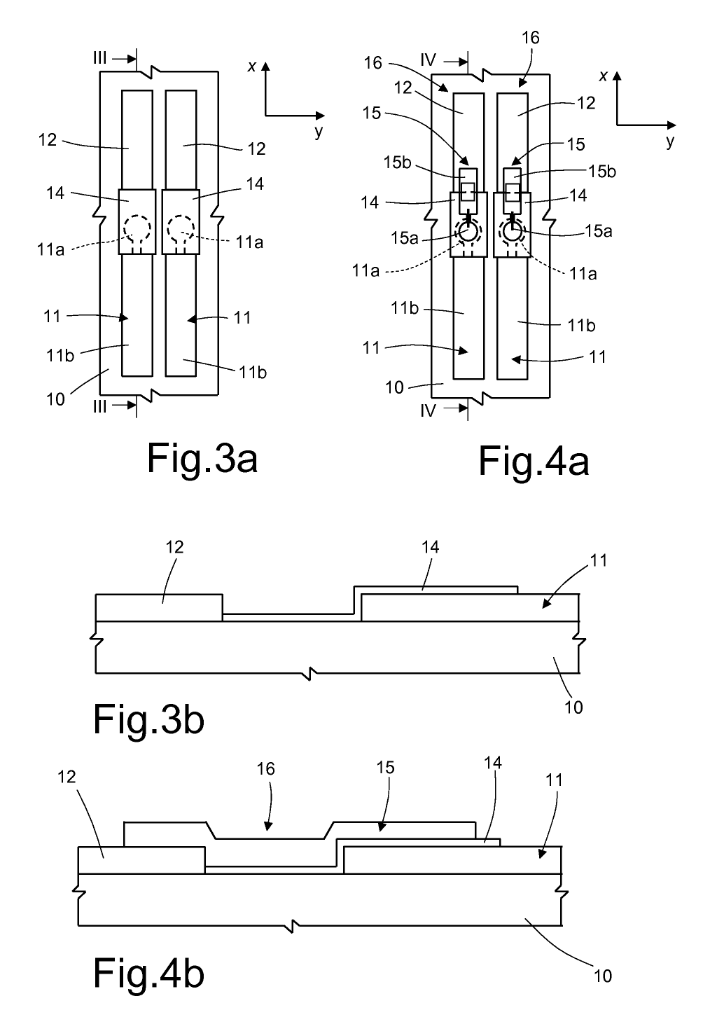

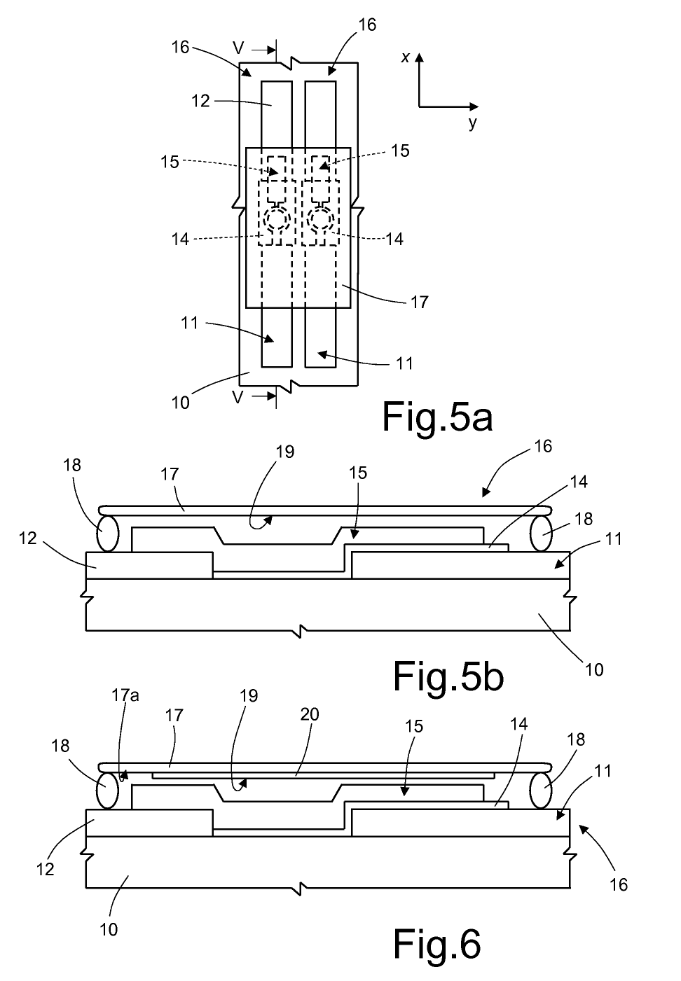

With reference to FIGS. 2a-2b (which are not drawn to scale, as neither are the subsequent figures), first electrodes (or anodes) 11 of the elementary components, and electrical contacts 12, are initially formed on a substrate 10 made of transparent material, for example, glass or plastic. As will be clarified, the electrical contacts 12 are designed to contact second electrodes of the elementary components so as to enable biasing thereof. A layer of transparent conductive material, for example ITO, is deposited on the substrate 10 and is then defined by means of a single process of photolithography and chemical etching.

In detail, each of the first electrodes 11 comprises an active portion 11a, having, for example, a substantially circular shape in plan view, and a biasing portion 11b connected to the active portion 11a and having a substantially rectangular shape in plan view with main extension in a first direction x. The first electrodes 11 extend parallel to one another, and are aligned and spaced from one another of a first distance of separation, in a second direction y, orthogonal to the first direction x.

The electrical contacts 12 also have a substantially rectangular shape in plan view, with main extension in the first direction x. Each of the electrical contacts 12 is aligned to a respective one of the first electrodes 11 along the first direction x, and is separated from the same first electrode 11 by a second distance of separation. The electrical contacts 12 extend parallel to one another along the second direction y, and are spaced from one another by the first distance of separation.

Next (FIGS. 3a-3b), the organic regions 14 of the elementary components are formed. The organic regions 14 extend on the active portions 11a of the first electrodes 11 and the region of the substrate 10 comprised between the same active portions 11a and respective electrical contacts 12. In addition, the organic regions 14 do not overlap the electrical contacts 12 and the biasing portions 11b of the first electrodes 11.

In particular, the organic regions 14 are defined by selective deposition or evaporation (“patterning”) of the organic material through appropriate deposition/evaporation masks (the so-called “shadow masks”), or else they are selectively deposited via the ink-jet printing technique, or via other known techniques allowing a deposition of organic material limited to well-defined areas on the substrate 10. According to an embodiment of the present invention, patterning of the organic material leads to the definition of an organic region 14 for each elementary component, and the various organic regions 14 are distinct, and separated from one another by a given distance of separation, in the second direction y.

Next (FIGS. 4a-4b), an evaporation of metal material, for example, aluminium (or another metal with high work function), or a sequential evaporation of calcium and aluminium (or other multi-layer material, even made of metals with low work function, which, however, entails a high reactivity), is performed through an appropriate shadow mask, for the formation of second electrodes (or cathodes) 15 of the elementary components. Each of the second electrodes 15 includes a respective active portion 15a and a respective biasing portion 15b. The active portion 15a extends above a respective active portion 11a of a first electrode 11, and has a substantially circular shape in plan view with a diameter smaller than that of the respective active portion 11a. The biasing portion 15b has a substantially rectangular shape in plan view with main extension in the first direction x, extends on an underlying organic region 14 and terminates on a respective electrical contact 12, contacting it electrically. The organic region 14 set between the active portions 11a, 15a respectively of the first and second electrodes 11, 15 consequently constitutes an electroluminescence region of the corresponding elementary component. The elementary components, designated by 16, of the organic electronic device are thus formed.

Next (FIGS. 5a-5b), an encapsulating plate 17, for example, made of glass or metal material, is applied on the organic electronic device so as to encapsulate the corresponding elementary components 16 to protect them from external agents, which could attack and degrade the materials forming the device and hence the device itself. In detail, the encapsulating plate 17 is glued by means of sealing resin 18, for example, epoxy resin, so as to define an encapsulation space 19 that surrounds and encloses completely the organic regions 14 and the second electrodes 15 of the elementary components 16. The sealing resin 18 is set between the encapsulating plate 17 and the biasing portions 11b of the first electrodes 11 on one side, and the electrical contacts 12 on the other, in an area corresponding to the elementary components 16, and is set between the encapsulating plate 17 and the substrate 10 elsewhere. The encapsulating plate 17 is sealed to the substrate 10 so as not to allow infiltration of degrading agents in the encapsulation space 19.

In particular, the electrical contacts 12, which exit from the encapsulation space 19 and contact the biasing portions 15b of the second electrodes 15 within the same encapsulation space 19, enable biasing from outside of the second electrodes 15 and prevent these from coming into contact with the external agents. Thanks to the adhesion of the sealing resin 18 to the material of which the first electrodes 11 and the electrical contacts 12 (in this case, ITO) are made, infiltration of gas or other external agents and damage to the organic regions 14 and the second electrodes 15 is prevented.

Gluing of the encapsulating plate 17 is carried out, for example, within a glove box, in an inert atmosphere (of nitrogen or pure argon) so as not to expose the materials of the organic regions 14 and of the second electrodes 15 to the action of the air, and prevent external agents from remaining trapped within the encapsulation space 19.

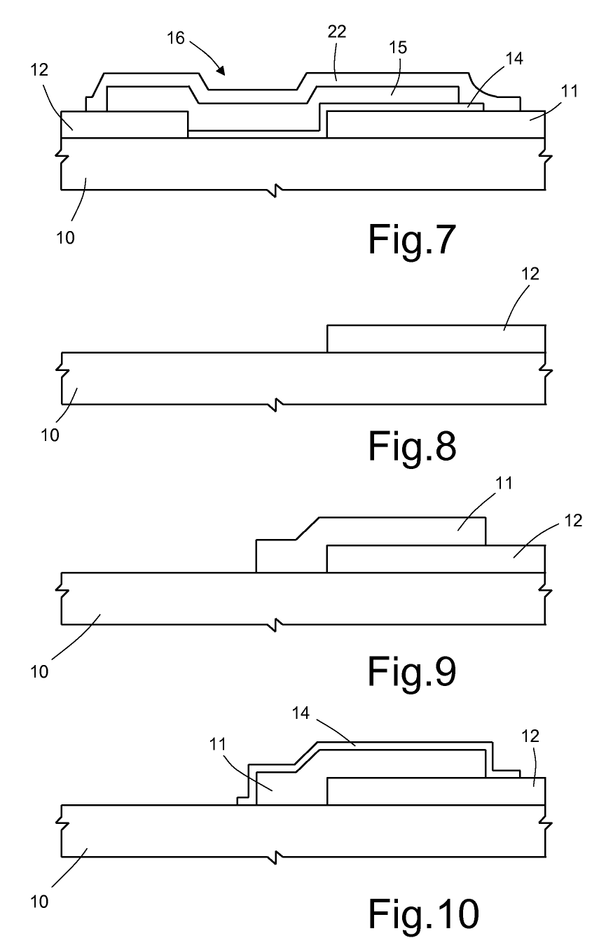

As illustrated in FIG. 6, on a surface 17a of the encapsulating plate 17 facing the encapsulation space 19, an absorption layer 20 (the so-called “dryer” or “getter”) may be provided, which is made, for example, of silica or calcium oxide. The absorption layer 20 absorbs possible atmospheric residue and capture molecules that may permeate the encapsulating materials, or possible by-products released from the resin during its hardening.

A variant of the manufacturing process, shown in FIG. 7, envisages deposition of an encapsulating layer 22 directly in contact with the elementary components 16 so as to leave exposed (for their electrical biasing) just parts of the electrical contacts 12 and of the biasing portions 11b of the first electrodes 11. This variant is particularly advantageous in the case where a substrate 10 made of flexible material is used in so far as also the encapsulating layer 22 can be made of flexible material. In a way not illustrated, also in this case the absorption layer 20 can be set between the encapsulating layer 22 and the encapsulated elementary components 16.

The encapsulating layer 22 can be deposited by means of various techniques, for example, by sputtering, ECR-CVD, spray-coating, spin-coating, adjusting the process conditions in order not to damage the organic regions 14 and the second electrodes 15. Furthermore, the material of the encapsulating layer 22 is electrically insulating and has sufficient barrier properties in regard to external agents. The encapsulating layer 22 may include one or more layers set on top of one another; for example, plastic, or inorganic materials, or a hybrid organic-inorganic multilayer can be used.

A second embodiment of the present invention envisages the formation of an organic electronic device comprising elementary components 16 of a top-emitting OLED type.

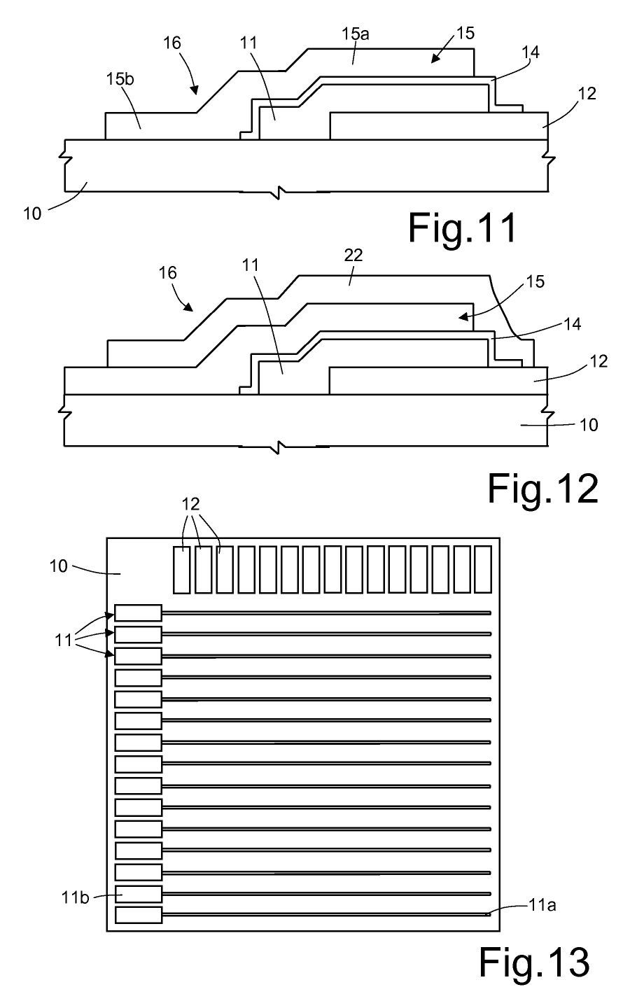

In detail (FIG. 8), the electrical contacts 12, made for example of ITO, are initially deposited on the substrate 10, which here can be made of an opaque material. In this case, the electrical contacts 12 are designed to contact the first electrodes 11 to enable biasing thereof from outside the encapsulation.

Then (FIG. 9), the first electrodes 11, made for example of aluminium, are defined by means of a photolithographic process (or selective deposition/evaporation); the first electrodes 11 are set partially on respective electrical contacts 12 (contacting them), and extend partially on top of the substrate 10.

Next (FIG. 10), the organic regions 14 of the elementary components 16 are defined, for example, by means of selective deposition or evaporation. The organic regions 14 coat completely respective first electrodes 11, and further extend partially on the substrate 10 and on respective electrical contacts 12. In a way substantially similar to what has been described previously (and not illustrated here), the organic regions 14, corresponding to each individual elementary component 16, are separate and distinct from one another, and also in this case, via the patterning technique, an organic region 14 is defined for each of the elementary components 16.

Then (FIG. 11), the second electrodes 15 are deposited; in this case, the second electrodes 15 are made of transparent conductive material, for example, ITO. Active portions 15a of the second electrodes 15 extend on respective organic regions 14, whilst biasing portions 15b of the same electrodes extend on the substrate 10.

The elementary components 16 thus formed are then encapsulated, in a way substantially similar to what has been described previously, for example, by means of deposition of an encapsulating layer 22 (FIG. 12) in direct contact with the second electrodes 15. The encapsulating layer 22 is in this case made of transparent material, for example, an epoxy resin including bisphenol F. The encapsulating layer 22 coats the organic regions 14 and the first electrodes 11 completely and leaves exposed just external portions of the electrical contacts 12 and the biasing portions 15b of the second electrodes 15. Again, an encapsulation is formed such as to protect the organic and metal materials with low work function (for example, aluminium) from external agents and to enable biasing of the elementary components 16 from outside; also in this case, the electrodes inside the encapsulation are contacted by means of conductive materials resistant to external agents, which exit from the encapsulation.

A possible absorption layer (not illustrated here) can be set between the encapsulating layer 22 and the encapsulated elementary components 16, positioned in such a way as not to shield the light radiation emitted by the organic regions 14 of the elementary components 16.

A third embodiment of the present invention envisages formation of an array of elementary components 16 of an OLED type, for example, for use in a pixel-array display.

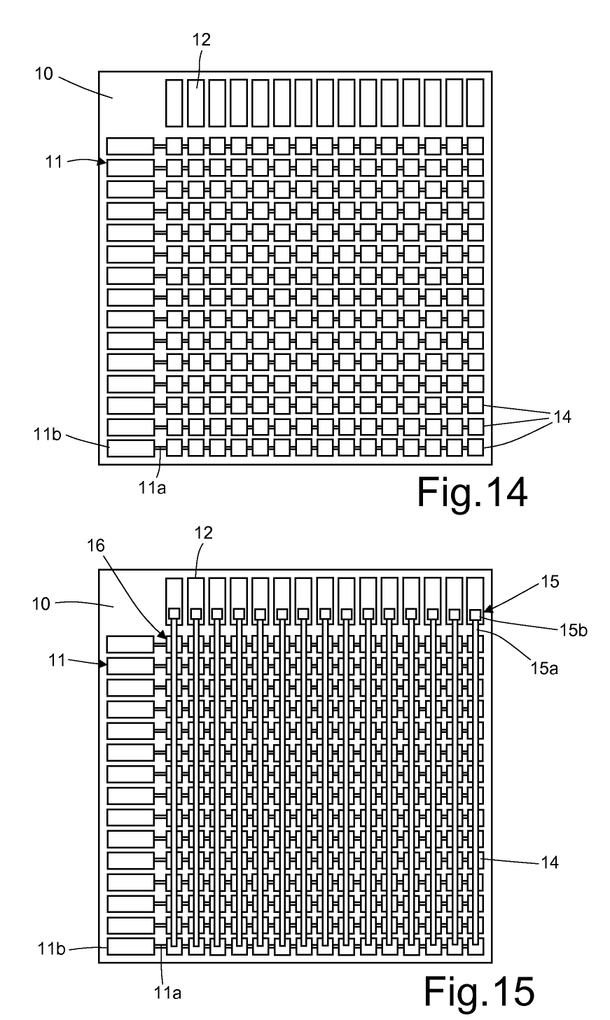

In detail (FIG. 13), during a single process of photolithography and etching of a layer of transparent conductive material, for example ITO, the first electrodes 11 and the electrical contacts 12 are initially formed on the substrate 10. The first electrodes 11 include active portions 11a, which are here to form row contacts of the array, and biasing portions 11b, each designed to bias a different row of the array. As will be clarified, each of the electrical contacts 12 enables biasing of a respective column of the array.

Then (FIG. 14), the organic regions 14 are formed (again via a selective patterning process) in the area corresponding to the intersections between the rows of the array, defined by the active portions 11a, and the columns of the array, defined ideally by the prolongations of the electrical contacts 12.

Next (FIG. 15), the second electrodes 15 of the elementary components are formed; the second electrodes 15 are made of metal with low work function and high reactivity, for example, aluminium. The second electrodes 15 include biasing portions 15b, set on respective electrical contacts 12 so as to contact them electrically, and active portions 15a, designed to form column contacts of the array and extending as a prolongation of the respective electrical contacts 12. The organic regions 14 at the intersection between the active portions 11a, 15a respectively of the first and second electrodes 11, 15 constitute individually addressable electroluminescent regions of the elementary components 16 of the array.

Again, at the end of the manufacturing process of the elementary components 16, encapsulation of the entire array is carried out. In particular (FIG. 16), an encapsulating plate 17 is positioned above the array, defining an encapsulation space (not shown here). As described previously, just some parts of the electrical contacts 12 and of the biasing portions 11b of the first electrodes 11 are not included within the encapsulation space. The encapsulating plate 17 is fixed with sealing resin (not illustrated here) set all along its contour, in such a way as to prevent the introduction of external agents within the encapsulation space. Again, deposition of an encapsulating layer directly in contact with the structures of the elementary components 16 can be envisaged as an alternative to the encapsulation plate 17; also in this case, the absorption layer may be provided.

The embodiments described have a number of advantages.

In general, these embodiments enable protection of the degradable materials of the organic electronic device from the action of environmental agents, blocking, or at least delaying, the processes of degradation of the same materials.

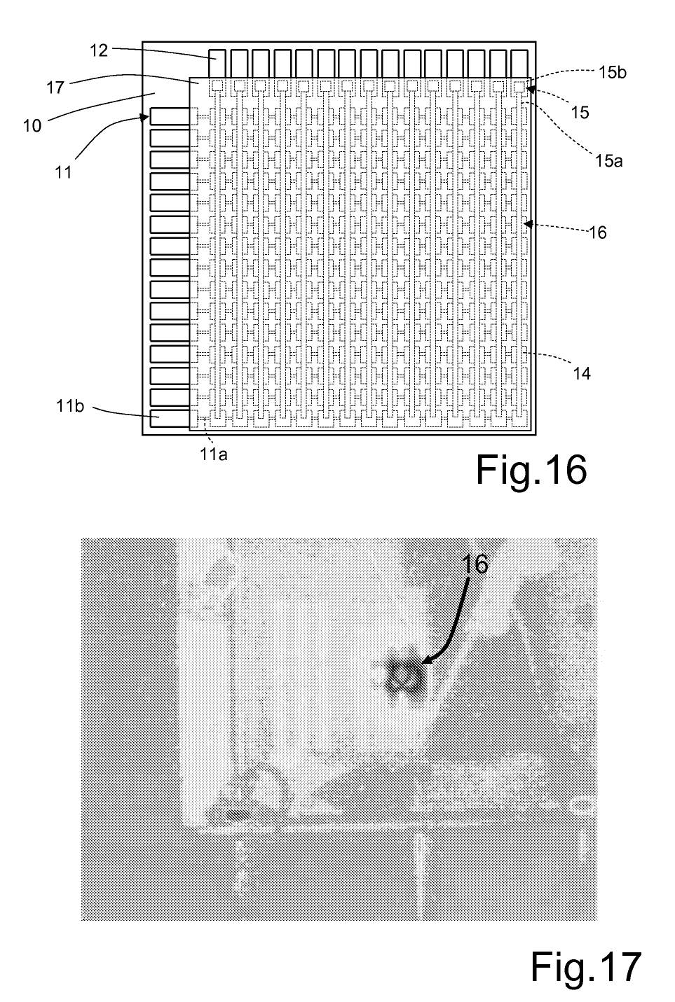

The patterning process, by means of which the various organic regions 14 of the elementary components 16 of the organic electronic device are separated from one another, prevents a degradation of the organic material, possibly induced in one of the elementary components 16, from having repercussions on adjacent components. This degradation can be caused by external agents, such as oxygen or water vapor, which nonetheless penetrate within the organic material, and can be aggravated by the heat generated within the individual elementary components 16 as a result of the passage of current. In fact, in a known way, by biasing the elementary components 16 with electrical quantities (voltages and currents) of high value in order to increase the emission of light radiation, a marked rise in temperature in the organic materials is generated, which can lead to their degradation. Advantageously, the interruption of the organic material between adjacent regions blocks, or markedly reduces, the propagation both of the external agents and of degradation. In this regard, FIG. 17 highlights how the heat generated within an elementary component 16 (indicated by the arrow) does not remain confined in said component but is propagated in adjacent elementary components 16, also through the substrate. Since the rise in temperature favors diffusion of the degradation and of the degrading agents through the organic material, thanks to the separation between the organic regions 14, this diffusion is considerably reduced.

The processes and devices formed thereby which have been described have further advantages associated to the decomposition into two distinct parts, in mutual electrical contact, of some biasing electrodes of the device. In fact, the double-contact structure of these electrodes, as previously described, envisages formation of:

an electrical contact 12, made of a conductive material that does not degrade in contact with external agents, arranged on the outside of the encapsulation space 19; and

an actual electrode, made of a metal with low work function (such as to ensure an adequate injection of electrons in the organic material) and, hence, having a marked tendency to oxidize, arranged within the same encapsulation space 19.

This decomposition enables the metal electrode to be completely enclosed in the encapsulation space 19, and hence be protected from the action of the external agents, whilst being biased from the outside via the corresponding electrical contact 12. The material of which the electrical contact is made, for example, ITO, is such as not to allow infiltration of external agents within the encapsulation space 19.

As previously highlighted, the use of absorption layers 20 within the encapsulation space 19 enables a considerable increase in the service life of the organic electronic devices.

Furthermore, the choice of ITO as material for the electrodes (first or second electrodes 11, 15 according to an embodiment) and for the electrical contacts 12, which exit from the encapsulation space 19, is particularly advantageous, in so far as ITO:

is a very compact material and hence does not allow the atmospheric gases to percolate through it and penetrate into the encapsulation space 19;

has an excellent adhesion to the substrate 10 so as not to cause detachment thereof in the event of mechanical stresses that might occur during the steps of manufacturing, and to the resins used for sealing the encapsulating plate 17, so as to prevent the atmospheric gases from infiltrating into the encapsulation space 19;

has good electrical conductivity and low contact resistance with aluminium (and with other metals with low work function) such as not to alter the electrical characteristics of the organic electronic devices; and

has an excellent resistance to the attack by atmospheric gases.

Furthermore, advantageously, substrates, either made of glass or made of plastic, having ITO layers already deposited thereon are commercially readily available at a low cost.

Finally, it is clear that modifications and variations can be made to what has been described and illustrated herein, without thereby departing from the scope of the present invention, as defined in the annexed claims.

In particular, it is clear that the described manufacturing process is readily applicable to devices having any type of geometry or structure, provided on rigid or flexible substrates 10, whether opaque or transparent; the substrates may be: organic, such as, for example, plastics, polymers, paper and fabric; inorganic, such as, for example, glass, silicon, metal and ceramic; and hybrid substrates, such as, for example, organic or inorganic multilayer materials.

Furthermore, the same process can be used for the manufacturing of further organic electronic devices of an optical type, such as, for example, photovoltaic cells, optical detectors and TFTs.

As a further variant, all the electrodes of the elementary components 16 can be made of a metal with low work function and be arranged entirely within the encapsulation space 19 and be contacted electrically by means of the double-contact structure described previously.

The electrical contacts 12 for the electrodes can also be divided into further distinct parts, electrically and mechanically connected to one another, at least one of which exits from the encapsulation space 19.

Elementary components and arrays of such components according to embodiments of the present invention may be included in a variety of different types of electronic devices and systems, such as cellular phones and other portable electronic devices, mice, laser pointers, televisions, video displays, computer systems, and so on.

From the foregoing it will be appreciated that, although specific embodiments of the invention have been described herein for purposes of illustration, various modifications may be made without deviating from the spirit and scope of the invention.

1. An organic electronic device, comprising:
a substrate;
at least one first elementary component and one second elementary component, arranged above said substrate, each of said first and second elementary components being provided with: a respective first electrode, arranged above said substrate; a respective region of organic material, arranged above said first electrode; and a respective second electrode, arranged above said region of organic material, at least partially in an area corresponding to said first electrode; and
an encapsulation structure defining an encapsulation space, isolated from an external environment and designed to protect said first and second elementary components from said external environment,
wherein the regions of organic material of said first and second elementary components are separated and distinct from one another, and are set entirely within said encapsulation space.

2. The device according to claim 1, wherein at least one between said first and second electrodes of said first and second elementary components is set entirely within said encapsulation space, and each of said first and second elementary components is further provided with an electrical-contact element, set at least partially on the outside of said encapsulation space and connected electrically to said at least one between said first and second electrodes.

3. The device according to claim 2, wherein said at least one between said first and second electrodes is arranged on said substrate.

4. The device according to claim 2, wherein said at least one between said first and second electrodes is made of a first conductive material having a first reactivity with respect to atmospheric agents, and said electrical-contact element is made of a second conductive material having a second reactivity with respect to said atmospheric agents, said first reactivity having a value higher than said second reactivity.

5. The device according to claim 4, wherein the other between said first and second electrodes includes an active portion set entirely within said encapsulation space, in contact with a respective region of organic material, and a biasing portion extending at least in part on the outside of said encapsulation space; said other between said first and second electrodes being made of said second conductive material.

6. The device according to claim 1, wherein said encapsulation structure is sealed to said substrate above said first and second elementary components, and in particular includes: an encapsulating plate coupled to said substrate by means of sealing resin; or else an encapsulating layer set on and in contact with said second electrodes.

7. The device according to claim 6, wherein said encapsulating plate or said encapsulating layer are made of transparent material.

8. The device according to claim 1, further comprising a plurality of further elementary components, arranged, with said first and second elementary components, to form an array.

9. The device according to claim 1, wherein said first and second elementary components are “top-emitting” or “bottom-emitting” OLEDs, photovoltaic cells, TFTs, optical detectors, or other electronic components made totally or in part of organic materials.

10. A process for manufacturing an organic electronic device, comprising the steps of:
providing a substrate;
forming first electrodes above said substrate;
forming regions of organic material above said first electrodes;
forming second electrodes above said regions of organic material, at least partially in an area corresponding to said first electrodes, each of said regions of organic material being set between a respective one of said first and second electrodes, thus forming a respective elementary component of said organic electronic device; and
forming an encapsulation structure defining an encapsulation space isolated from an external environment, and designed to protect the elementary components from said external environment,
wherein said step of forming regions of organic material comprises the step of selectively defining said regions of organic material in the area corresponding to said first electrodes so that said regions of organic material are separated and distinct from one another; and in that forming an encapsulation structure comprises arranging said encapsulation structure so that said regions of organic material are arranged entirely within said encapsulation space.

11. The method according to claim 10, wherein said step of selectively defining comprises the step of depositing or evaporating selectively said regions of organic material.

12. The method according to claim 10, further comprising forming electrical-contact elements during said step of forming first electrodes; wherein said step of forming second electrodes comprises electrically contacting said second electrodes with said electrical-contact elements; and said step of forming an encapsulation structure comprises arranging said encapsulation structure so that said second electrodes are set entirely within said encapsulation space, and said electrical-contact elements are set partially on the outside of said encapsulation space.

13. The method according to claim 10, further comprising forming electrical-contact elements above said substrate; wherein said step of forming first electrodes comprises electrically contacting said first electrodes with said electrical-contact elements, and said step of forming an encapsulation structure comprises arranging said encapsulation structure so that said first electrodes are set entirely within said encapsulation space, and said electrical-contact elements are set partially on the outside of said encapsulation space.

14. The method according to claim 12, wherein said first or second electrodes are made of a first conductive material having a first reactivity with respect to atmospheric agents, and said electrical-contact elements are made of a second conductive material having a second reactivity with respect to said atmospheric agents, said first reactivity having a higher value than said second reactivity.

15. The method according to claim 10, wherein said step of forming an encapsulation structure comprises sealing said encapsulation structure to said substrate above said elementary components, and in particular: coupling an encapsulating plate to said substrate by means of a sealing resin; or else depositing an encapsulating layer on and in contact with said second electrodes.

16. The method according to claim 15, wherein said encapsulating plate or said encapsulating layer are made of transparent material.

17. An electronic device, comprising:
electronic circuitry including at least one organic electronic device, the organic electronic device having a substrate and further including,
a plurality of elementary components arranged on a region of the substrate, each of the elementary components within the region having a first electrode, an organic region element adjoining at least a portion of the first electrode, and a second electrode adjoining at least a portion of the organic region element, and each of the elementary components in the regions being physically separated from the other elementary components; and
an encapsulation structure formed over the structure defined by the substrate and the plurality of elementary components, the encapsulation structure forming an encapsulation space that entirely encapsulates the organic regions of the plurality of elementary components within the region.

18. The electronic system of claim 17 wherein the electronic circuitry comprises cellular telephone circuitry.

19. The electronic system of claim 17 wherein the electronic circuitry comprises video display circuitry.

20. The electronic system of claim 17 wherein for each elementary component within the region at least one of the first and second electrodes is formed directly on the substrate.

21. The electronic system of claim 17 wherein for each elementary component within the region at least one of the first and second electrodes is transparent to light generated by the organic region element during operation of the system.

22. The electronic system of claim 17 wherein the substrate comprises one of glass and plastic.

23. The electronic system of claim 17 wherein the encapsulation space includes an absorption layer formed within the encapsulation space.

24. The electronic system of claim 17 wherein each of the elementary components within the region comprises an OLED.
